(19) United States
(12) Patent Application Publication
(10) Pub. No.: US 2019/0152067 A1
(43) Pub. Date: May 23, 2019

(54) GRIPPING TOOL, GRIPPING DEVICE, AND GRIPPING METHOD

(71) Applicant: KUKA Systems GmbH, Augsburg (DE)

(72) Inventors: Otmar Honsberg, Fürstenfeldbruck (DE); Jürgen Proske, Neusäss (DE); Tom Clauder, Augsburg (DE)

(21) Appl. No.: 16/313,772

(22) PCT Filed: Jun. 26, 2017
(86) PCT No.: PCT/EP2017/065680

§ 371 Date: Dec. 27, 2018

(30) Foreign Application Priority Data
Jun. 27, 2016 (DE) 20 2016 103 393.4

(51) Int. Cl. B25J 15/00; B25J 15/02; B65H 67/06; H05K 13/04

(52) U.S. Cl. CPC B25J 15/0047; B25J 15/0213; B65H 2701/37; H05K 13/0404; H05K 13/0419; B65H 67/065

(57) ABSTRACT

A gripping tool, a gripping device, and a gripping method for reel-type and/or disk-type gripping objects, in particular SMD rolls. The gripping tool, which can be automatically handled and operated, has a frame having a connection, in particular a robot connection, and has a gripper having a controllable adjusting device, wherein the gripper is provided and designed for laterally guiding and for centrally gripping and supporting the gripped object.

### CROSS-REFERENCE TO RELATED APPLICATIONS

This application is a national phase application under 35 U.S.C. § 371 of International Patent Application No. PCT/EP2017/065680, filed Jun. 26, 2017 (pending), which claims the benefit of priority to German Patent Application No. DE 20 2016 103 393.4, filed Jun. 27, 2016, the disclosures of which are incorporated by reference herein in their entirety.

### TECHNICAL FIELD

The invention relates generally to apparatus and methods for handling objects and, more particularly, to a gripping tool, a gripping device, and a gripping method for handling objects.

### BACKGROUND

From actual practice, it is known to load surface mount device (SMD) component placement machines with SMD rolls, in which the SMD components are arranged on a rolled-up carrier tape or carrier belt. The SMD rolls are manually gripped and loaded and unloaded.

It is the object of the present invention to demonstrate an improved gripping method.

### SUMMARY

The invention achieves this object with the features of the gripping tool and method as shown and described herein.

The gripping tool and the gripping device along with the gripping method, have various advantages.

The gripping tool can be handled and operated automatically. It can guide reel-like and/or disk-like gripped objects, preferably SMD rolls or similar, and grip as well as support them preferably in a central manner and also release them again. Such gripped objects have for example a diameter that is greater than their thickness. In addition, it is possible to hold and bear such a gripped object in a centrally rotatable manner, and to allow its rotation in a gripped state. Alternatively, non-rotational gripping and bearing is possible.

For these functions, the gripping tool has a suitable structural design that can vary. By means of a detection device on the gripping tool, the correct gripping and if applicable release of gripped object can be recorded and monitored. The gripping tool can be moved by means of a programmable handling device, particularly an industrial robot, and be utilized for automatically transporting as well as receiving and releasing said gripped objects.

The gripping tool has a frame with a connection for a programmable handling device, particularly a robot connection, and a gripper with a controllable adjusting device. Using the adjusting device, the gripper along with its gripping functions can be driven and controlled. The gripper is designed for laterally guiding as well as centrally gripping and supporting as well as rotatably bearing a gripped object if applicable. Guiding, gripping, supporting and bearing can take place from one side or multiple sides, particularly on both sides.

The claimed gripping technology is advantageous particularly for narrow reel-like or roll-like gripped objects. These can be automatically fed to a processing device, e.g., a placement machine, and removed. They can be held or released there. A reel-like or roll-like gripped object can be held or borne particularly in a rotating manner, and can be rotated in this position at the gripper if needed. During the rotation, a tape arranged on the gripped object, particularly a reel, can be wound up or unwound.

This is particularly favorable when the ends of reeled-up or wound-up tapes, particularly carrier tapes or carrier belts for SMD components, are connected manually or automatically to each other. This can occur, e.g., by a so-called splicing operation, wherein the gripping tool or the gripping device brings into position the tape reel or SMD roll for this connection or splicing process and thereby keeps it rotatable. The tape reel or SMD roll can then be transferred to a provided receptacle on the processing device, e.g., a rack, and replace the used-up, empty tape reel or SMD roll.

The reeled-up or wound-up tape can be fed and transferred by a feed device arranged on the gripping tool to the processing device. This feed and if applicable also the splicing process can occur automatically, semi-automatically or manually. The connecting process, particularly the splicing process, can also be replaced by a form-fitting guide and a common transport of the used-up tape end and the new, fed-in tape end. The tape ends are thereby guided end-to-end in succession or they can also overlap each other.

In one embodiment, the gripper has a support arm with an end-positioned controllable gripping means, which is designed for centrally gripping and supporting as well as, if applicable, for rotatably bearing a gripped object at its central recess. On the other end, the support arm may be connected to the frame of the gripping tool. The gripping tool is suited for receiving one or more gripped objects.

There may be one or more support arms. Multiple parallel support arms may guide a gripped object on both sides. The support arm can have an elongated, flattened, particularly plate-like shape and extend away from the frame. A compact and space-saving design is hereby achieved, which can grip multiple gripped objects arranged side by side and specifically grasp one gripped object. A support arm adjustably positioned on the frame of the tool allows for adjustments to various dimensions, particularly thicknesses, of the gripped object.

On one or more support arms, the gripper may have on each a controllable gripping means, which allows for said centrally gripping and supporting one or more gripped objects. The gripping means may be designed in particular as a gripping finger. This may be a single gripping finger. The gripping means may be present as a plurality. Multiple opposing gripping means may interact and together form a support and if applicable a rotatable bearing for a gripped object.

The gripping means can be controllable, wherein it may be connected to the adjusting device of the gripping tool. In particular, the gripping means may be moved back and forth in a driven and controlled manner between a release position and a central engagement position on the gripped object. The kinematic system may vary. It may be a rotational movement, for example. Alternatively, a translational motion oriented transversely or obliquely to the support arm, or a combined rotational and translational motion, is possible.

In one embodiment, the gripping means may have in each case a control rod running along the support arm and preferably rotatable about its longitudinal axis and having a lateral projection at the end, which forms a support or rotary bearing when engaging in a central recess of the gripped object. The projection may be designed as a support and bearing lug. The projection is moved by the control rod motion, particularly by its rotation. In another design, the lateral projection may be moved by means of a wedge gear, a fluidic or magnetic actuation or by other means, if applicable against a springy return element.

The gripping device for reel-like and/or disk-like gripped objects, particularly SMD rolls, may have a single- or multi-axis, moveable, programmable handling device with a rigidly or detachably mounted gripping tool of the described type.

In one embodiment, the handling device is designed as a multi-axis, programmable industrial robot. The handling device, particularly the industrial robot, may have an assigned sensor system, which records external loads. At the mounting position, the sensor system may be arranged between the output element of the handling device and the gripping tool. Alternatively or additionally, it may be integrated in the handling device, particularly in a multi-axis industrial robot.

The handling device or the industrial robot may obtain sensing capabilities via the sensor system. These are advantageous to search for and specifically grip said gripped object. In addition, an exact positioning of the gripped object, particularly its release, can be achieved. The sensor system allows in particular searching for the gripped object by touch, controlling the exact and positionally correct gripping and supporting of the gripped object as well as its rotatable bearing if applicable. The exact position, particularly release position, of the gripped object can also be searched for and detected by touch.

The above and other objects and advantages of the present invention shall be made apparent from the accompanying drawings and the description thereof.

The invention is schematically depicted in the drawings for illustrative purposes.

### BRIEF DESCRIPTION OF THE DRAWINGS

The accompanying drawings, which are incorporated in and constitute a part of this specification, illustrate exemplary embodiments of the invention and, together with a general description of the invention given above, and the detailed description given below, serve to explain the principles of the invention.

FIG. 1 depicts a gripping device with an industrial robot and a gripping tool as well as a gripped reel-like gripped object in a cut-off, perspective view.

FIG. 2 is a magnified perspective individual perspective of the gripping tool and the gripped object of FIG. 1.

FIG. 3 is a perspective view of the opened gripping tool of FIGS. 1 and 2 without a gripped object.

FIG. 4 is a cut-off side view of the gripping tool with a gripped object according to FIGS. 1 and 2.

FIGS. 5 and 6 are cross-sectional views of the gripped object and the gripping tool in a release position and in a gripping position according to section lines V-V and VI-VI of FIG. 4.

FIG. 7 is a cut-off side view of the gripping tool with a gripped object according to FIGS. 1 and 2.

FIG. 8 depicts a processing device with a gripping device.

FIG. 9 depicts a gripping tool with a feed device for a tape in a perspective view.

FIG. 10 is a side view of the gripping tool according to arrow X of FIG. 9 along with a robot part.

FIG. 11 is a perspective view of the feed device of FIGS. 8 and 10 with a tape.

### DETAILED DESCRIPTION

The invention relates to a gripping tool (2) for a reel-like and/or disk-like gripped object (4) as well as a gripping method. The invention also relates to a gripping device (1) having a handling device (3) and a gripping tool (2) guided by the latter along with a method.

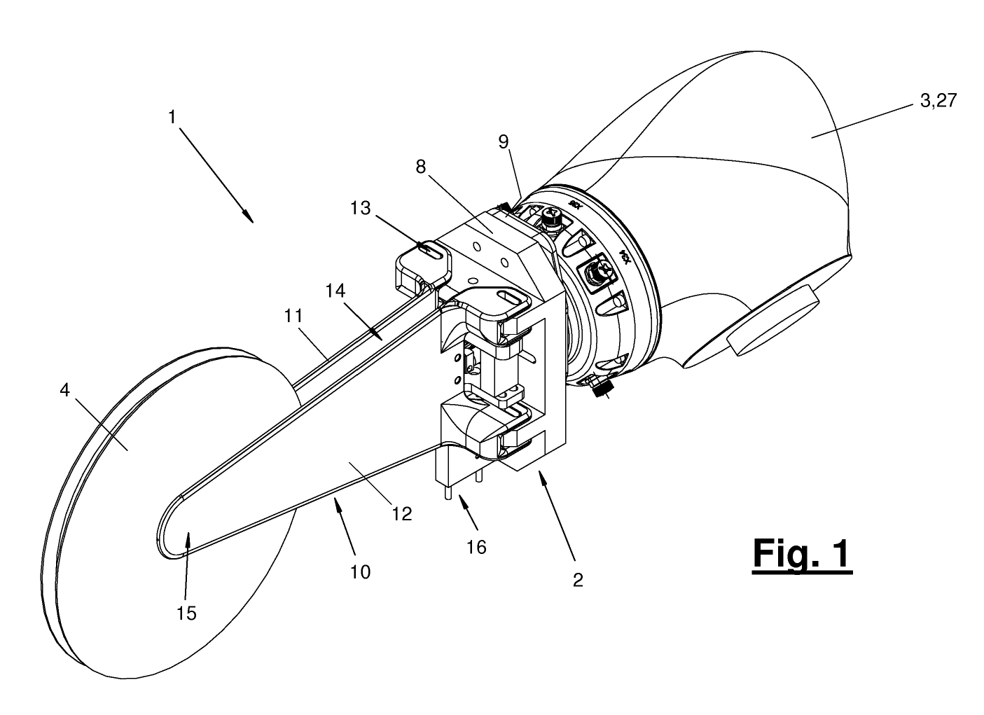

The depicted gripped object (4) is constructed in a reel-like and roll-like manner. For example, according to FIGS. 1 and 4 to 6, it has a circular disk-like shape. It may have a circular circumference and essentially plane side surfaces. Its diameter is greater than its thickness. Alternatively, the disk shape may look different.

The gripped object (4) has a cylindrical body (5) with a receiving groove on the outer circumference for a wound-up tape (6) or a belt. This may be for example a carrier tape for SMD components. These may be for example electronic components for assembling a circuit board or similar as surface-mounted devices (SMD). The body (5) forms a reel body.

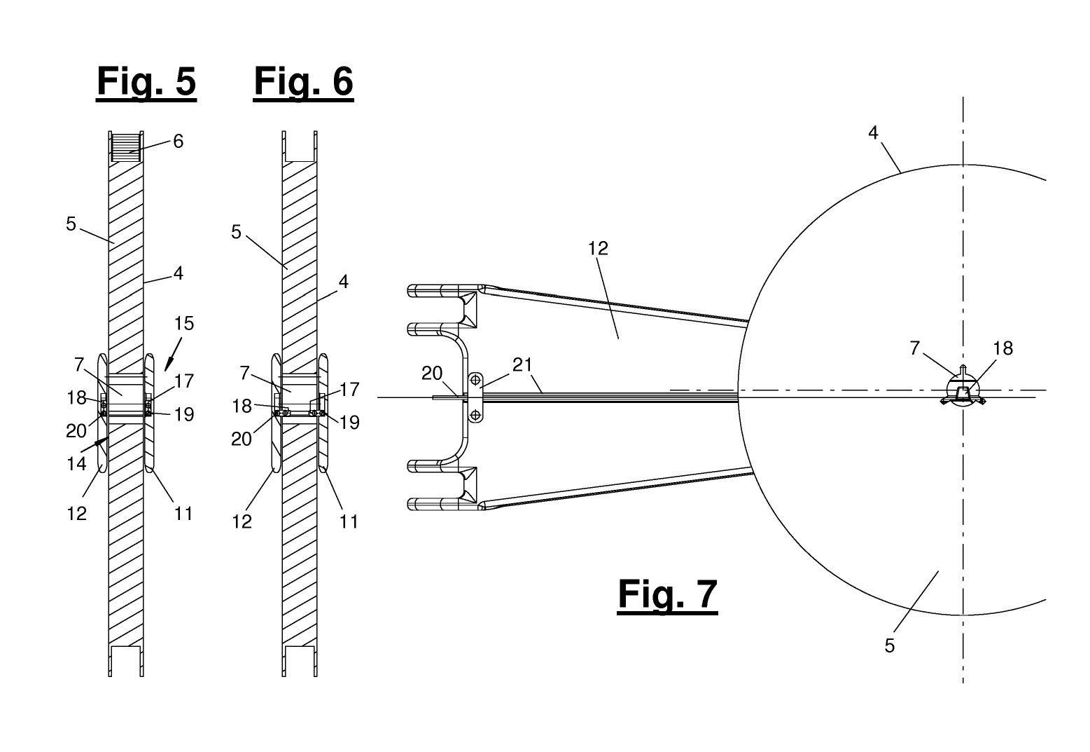

The diameter of the disk-like body (5) is preferably substantially larger than its thickness. In the middle, the gripped object (4) or the hub of the reel body has a preferably central recess (7) on one or both sides. The recess (7) may be designed as a groove or blind hole or, according to FIGS. 5 and 6, as a through-hole through the body (5). It may have any shape, e.g., cylindrical with radial recesses on the edge. It may thereby receive a drive hub with radial dogs.

The gripping tool (2) may be handled and operated automatically. To this end, it may be mounted on a programmable handling device (3). This may be a detachable connection, e.g., by means of a change coupling. The latter may have a media coupling for transferring operating resources, e.g., fluids, electrical signal and/or power currents or similar. The programmable handling device (3) is preferably designed as a multi-axis, programmable industrial robot. The gripping tool (2) is thereby installed on a preferably rotating drive element (28) of the handling device (3) or the industrial robot.

The gripping tool (2) has a frame (8) having a connection (9) for the handling device (3). The latter is preferably designed as a robot connection. It may have mechanical connection means and if applicable also connection means for said operating resources. The frame (8) also has a gripper (10) with a controllable adjusting device (16).

The gripper (10) is designed to laterally guide one or more reel- or roll-like gripped objects (4), as well as to grip and support them centrally. The gripper (10) can also bear the gripped object (4) in a centrally rotatable manner if necessary. It can rotate in a gripped state, wherein the bearing on the gripper (10) may be freely rotatable and the rotating force comes from outside.

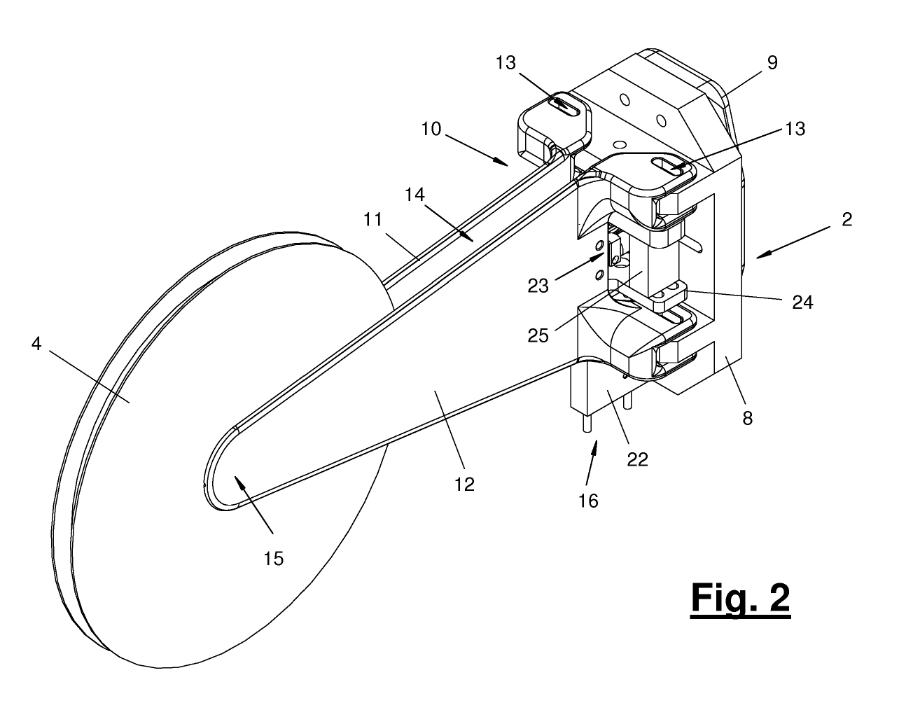

The gripper (10) can have a different structural design for the aforementioned functions. FIGS. 1 to 7 show a preferred embodiment.

The gripper (10) has a support arm (11, 12), having on the end a controllable gripping means (15), which is designed for centrally gripping and supporting as well as rotatably bearing, if applicable, a gripped object (4) at its central recess (7).

Alternatively, multiple gripped objects (4) can be gripped, supported and possibly rotatably borne side-by-side and/or successively as well as jointly or individually. The embodiment for a single gripped object (4) described below can be adapted correspondingly.

The gripper (10) may have a single support arm (11, 12) having on the end a gripping means (15), which guides, grips, and supports as well as rotatably bears a gripped object (4) on one side. Preferably, the gripper (1) has multiple, particularly two, support arms (11, 12), which run parallel and form between themselves an open space (14), in which a gripped object (4) can be held. The parallel arrangement can be exactly parallel or slightly conical. The main planes of the support arm(s) (11, 12) and gripped object (4) are oriented parallel in the gripping position.

As another variation, the particularly two support arms (11, 12) may be designed to have different lengths to be able to grip or “thread” the gripped objects (4) more simply. For example, using the leading support arm (11 or 12) in combination with a sensing robot or sensing-designed gripping tool (2), the gripped objects (4) can touch the rolls and then be inserted or introduced or “threaded” more easily in the intermediate gap between the two support arms (11, 12).

The support arm(s) (11, 12) have an elongated and flattened shape. The preferably plate-like designed support arms can have, from a side view, a wedge-shaped form, which tapers towards one end, on which the gripping means (15) is arranged. The support arm(s) protrude away from the frame (8). The wider arm end points to the frame (8). The support arm(s) (11, 12) are borne immovably or adjustably by means of a bearing (13). The frame (8) may be designed in a flange-like or plate-like manner for example, wherein it has arranged on its front face the gripper (10) with the support arm(s) (11, 12) and the connection (9) on its rear face.

The support arms (11, 12) are designed to be sufficiently long that diverse gripped objects (4), particularly rolls or disks, can be grasped. This can preferably occur in a diameter-independent manner.

The design of the bearing (13) can vary. For example, it may involve a sliding bearing, which allows for an adjustment transversely to the longitudinal direction of the support arms (11, 12). By means of this, the arm separation distance or the width of the open space (14) can be adjusted. Alternatively or additionally, the bearing (13) can be designed as a pivot bearing for example, which allows a flip-opening and -closing or opening and closing of the support arms (11, 12) and is connected to the actuator (16) if applicable. To form the bearing (13), the support arm(s) (11, 12) may have, distanced on the rear end (2) for example, bearing attachments with elongated holes that grasp the frontally protruding bearing flange on the frame (8) and are here rigidly or detachably and adjustably connected by bolts and clamping means if applicable.

Furthermore, the bearing (13) may also be equipped with an actuator system (e.g., lifting cylinder, motor-spindle combination) to allow one to automatically adjust one or both support arms (11, 12). A parallel gripping function can hereby also be achieved.

The support arms (11, 12) each have a controllable gripping means (15), which can be connected to the actuator (16). The gripped object (4) is laterally gripped on one or both end faces by the support arm(s) (11, 12) and guided. The controllably movable gripping means (15) effectuates the central gripping and supporting as well as the rotatable bearing, if applicable, of the gripped object (4) on the gripper (10).

The design of the gripping means (15) may vary and may have various kinematic systems. In the depicted embodiment, it is designed as a gripping finger. Both support arms (11, 12) can thereby each have a gripping means (15) or a gripping finger. The multiple gripping means (15) jointly effectuate the central gripping, supporting and if applicable the rotatable bearing of the gripped object (4). Alternatively, only one support arm (11, 12) may have a gripping means (15).

The adjusting device (16) acts on one single or multiple gripping means (15). It thereby drives them and controls their movements.

The gripping means (15) can be designed and arranged in various ways. In the depicted embodiments, it has in each case a control rod (19, 20) running along the support arm (11, 12) with a lateral projection (17, 18) on the end. The projection (17, 18) is designed as a support and bearing lug. It is preferably designed in a wedge shape and is adapted to the size of the central recess (7) of the gripped object (4). The projection (17, 18) grips from the outside into the recess in a mechanical manner. This can take place for example by a rotational movement. To this end, the for example flange-like or disk-like projection (17, 18) has appropriate dimensions.

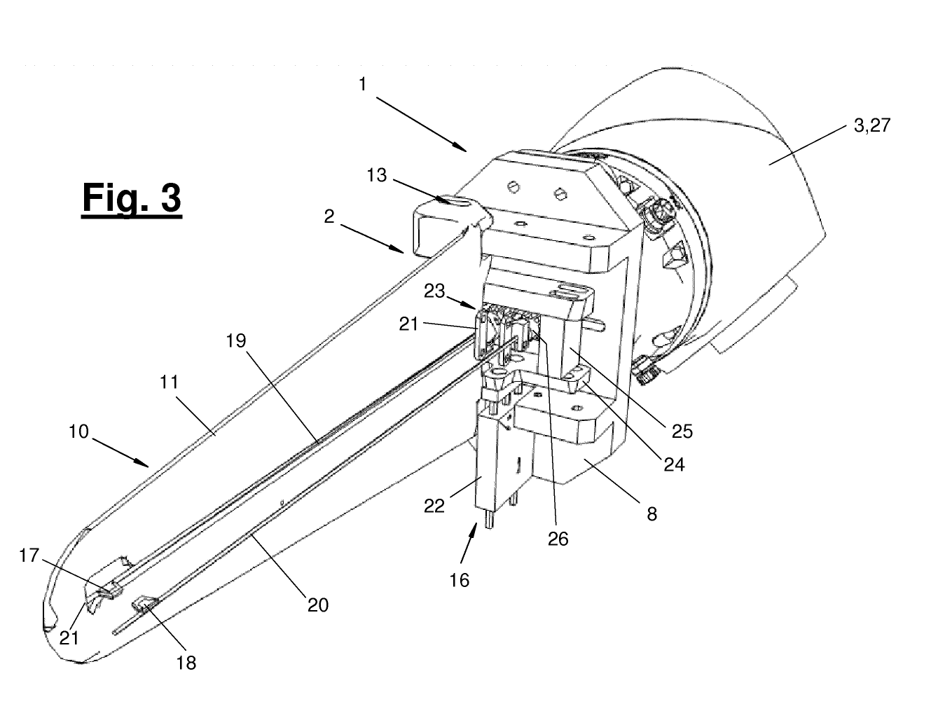

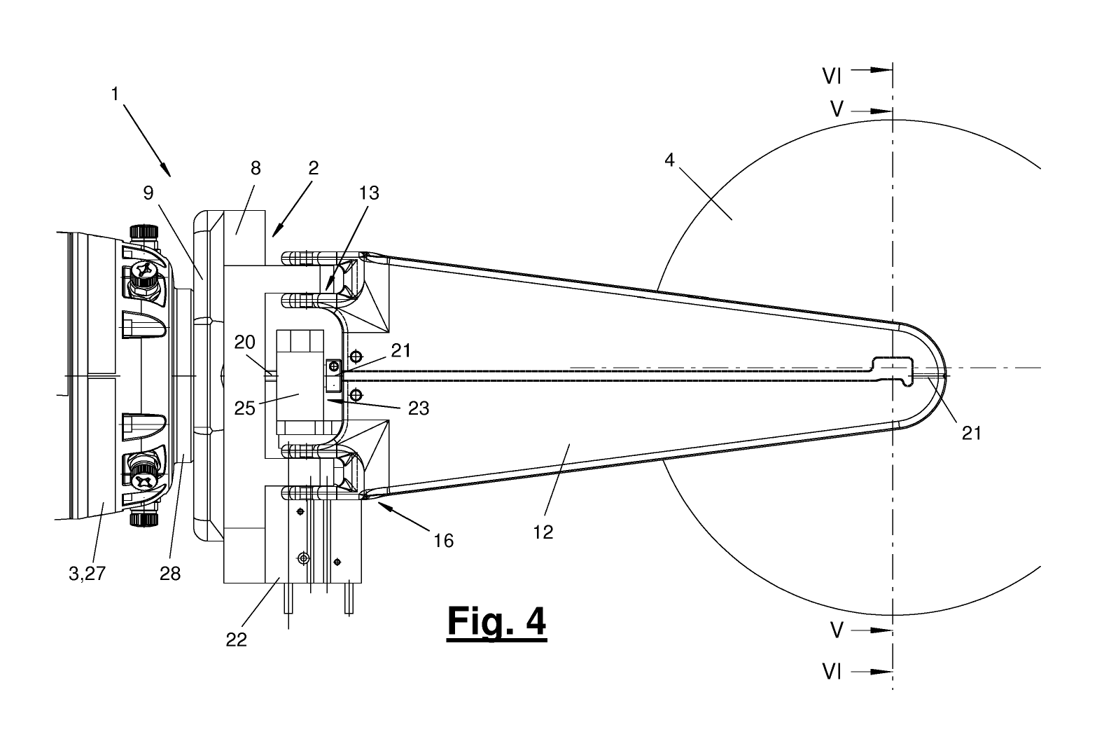

The control rod (19, 20) is rotatably borne on the gripper (10), particularly on the respective support arm (11, 12). For that purpose, a rod bearing (21) is provided, which for example has a rear bearing shell on the rearward and broadened end of the support arm (11, 12) and an axial insertion opening for a front-end rod extension on the front end of the arm. FIGS. 3, 4, and 7 depict this design. The control rod (19, 20) is held by the rod bearing (21), for example rotatably about its longitudinal axis and rigidly or in a limitedly displaceable manner in the axial direction. The support arm(s) (11, 12) may have on the front end on the interior side a recess for receiving the projection (17, 18). FIGS. 3 and 4 depict this design.

The control rod(s) (19, 20) is/are connected on the other end facing away from the projection (17, 18) to the adjusting device (16). The adjusting device (16) drives the control rod(s) (19, 20) and rotates the respective projection (17, 18) into the gripping and supporting position, on the one hand, and the releasing position, on the other.

The adjusting device (16) is arranged on the frame (8) of the gripping tool (2). It has a controllable actuating drive (22) with a gear unit (23) for actuating one or more gripping means (15), particularly one or more control rods (19, 20). The controllable actuating drive (22) has for example a fluidic cylinder, an electrical spindle or rack-and-pinion drive or another drive means. The gear unit (23) is for example designed according to FIG. 3 as a rack-and-pinion drive and converts the linear drive motion of the actuating drive (22) into a rotational movement of the control rod(s) (19, 20). At the control rod(s) (19, 20), there is arranged in each case on the end a gear wheel (26), which meshes with a rack (25), which is arranged on a yoke (24) connected to the actuating drive (22). In the depicted design, the actuating drive (22) can controllably drive both control rods (19, 20) synchronously with a counter-rotating rotation. The adjusting device (16) or the actuating drive (22) can for example have a step or servo motor, by means of which exact angle adjustments can be executed.

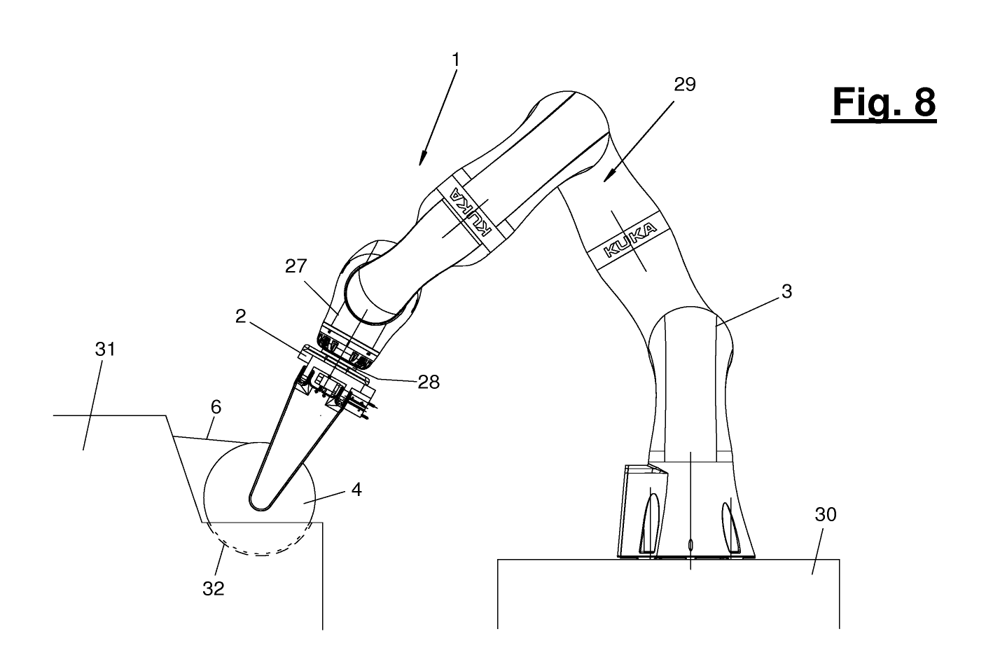

The single- or multi-axis, movable and programmable handling device (3) is designed for example in the previously mentioned manner as a multi-axis, programmable industrial robot according to FIG. 8. It can have multiple translational and/or rotational robot axes as well as multiple robotic limbs. FIGS. 1 and 3 depict an end member (27) of the handling device (3) or the industrial robot with a preferably rotating drive element (28) assembly-jointed to the connection (9).

The handling device (3) or the industrial robot guides the gripping tool (2) and transports with it the received gripped objects (4). The handling device (3) can thereby be arranged in a stationary manner or on a transport means (30) moved in a manual or automatic manner. It delivers the gripped objects (4) to a processing device (31) depicted in FIG. 8. The latter device can be for example a placement machine for SMD components. The gripped object (4) may be inserted or positioned in a pan-like reel holder (32) for example. The unwound tape (6) can be inserted into the processing device (31).

The handling device (3) has an assigned sensor system (29), which records and evaluates external loads, as well as transmits them to a control unit, particularly a robot control unit. The sensor system may be one component or multiple components, and may have one or more load-recording sensors, e.g., force and/or torque sensors. It may also have one or more other sensors, e.g., for path measurement, angle measurement or similar.

The sensor system (29) may be assigned in various ways to the handling device (3). It may for example be arranged between the connection (9) and the drive element (28) of the handling device. It may also be integrated in the gripping tool (2). In the depicted and preferred embodiment, the sensor system (29) is integrated in the industrial robot (3). At one or more robot axes, particularly at their bearings, there may be in each case a load-recording sensor and if applicable one additional sensor in a suitable number and arrangement.

The handling device (3) is preferably designed as a tactile industrial robot with sensing capabilities and with said integrated sensor system (29). The sensing capability may be used for searching for and gripping a gripped object (4) and for its delivery or positioning at a processing device (31). They are also an advantage for other processes, e.g., when splicing the tape (6).

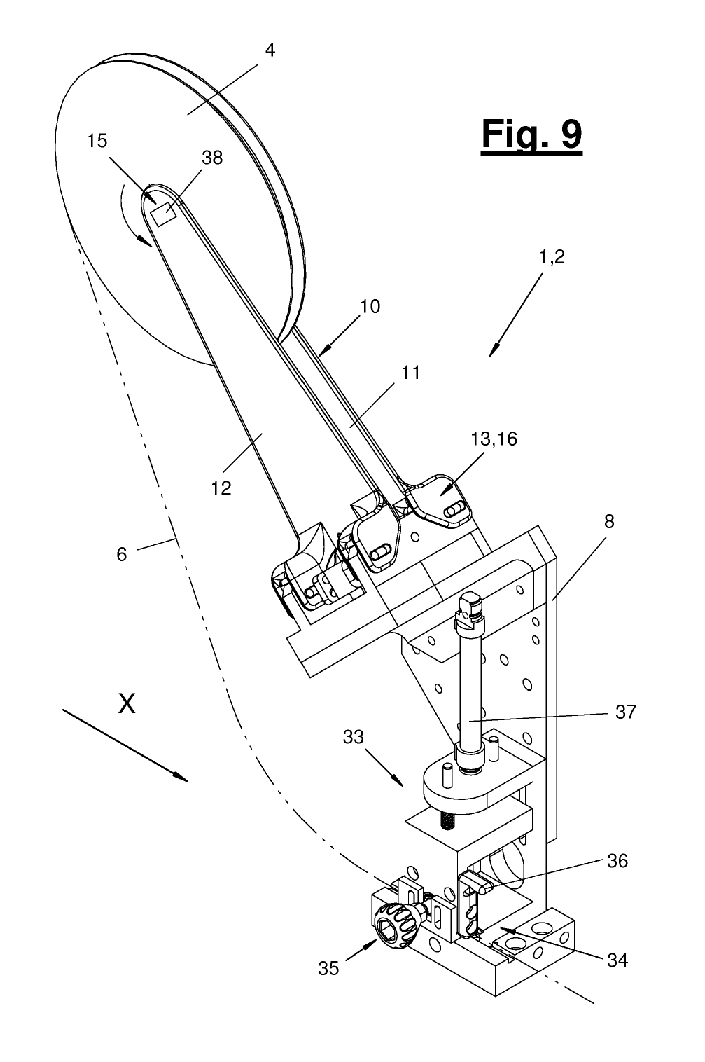

In the embodiment of FIGS. 9 to 11, the gripping tool (2) has a feed device (33) for the tape (6). The feed device (33) is arranged on the frame (8). It is preferably located at the rear end of the gripper (10) and is arranged with a clearance from gripped object (4) or the gripping means (15). The frame (8) has an angled shape, wherein the robot connection (9) is arranged in a position rotated by 90° for example compared to the first embodiment. The gripping tool (2) can otherwise be designed as in the first embodiment of FIGS. 1 to 8.

The feed device (33) is used to feed the tape (6) of the gripped object (4) to the processing device (31). The tape (6) can hereby be precisely guided, secured and positioned at a transfer point. The feed device (33) can also be used for actuating parts of the processing device (31), e.g., a latch of a tape (6) guide and drive device there. The feed device (33) can thereby be guided by the preferably tactile handling device (3) and controlled in its functions.

The feed device (33) may have one or more components.

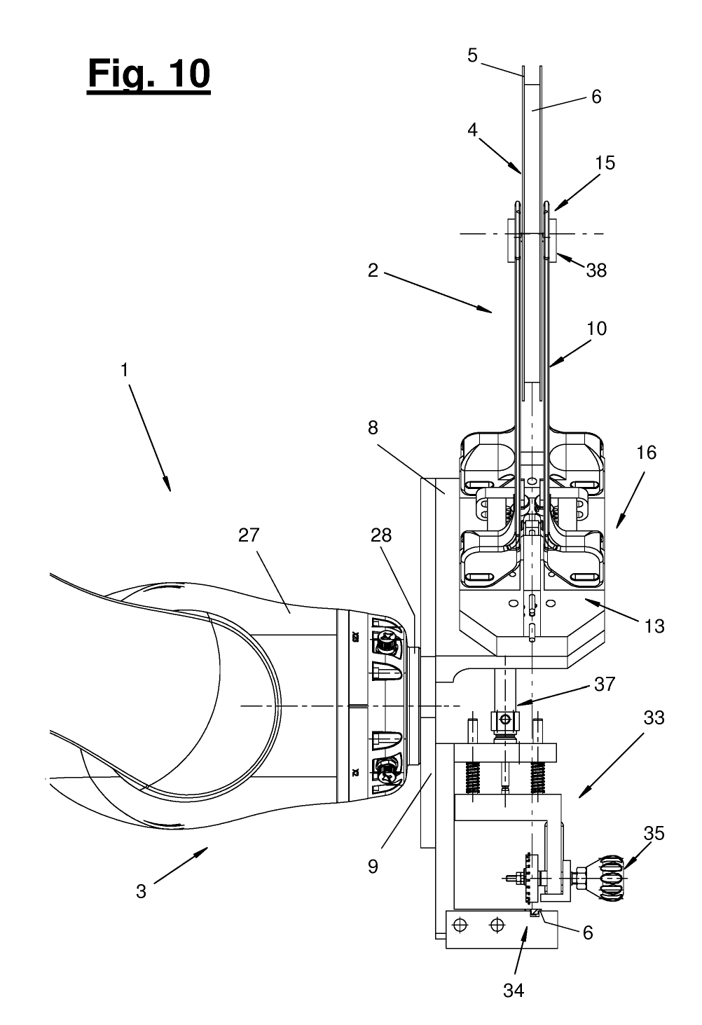

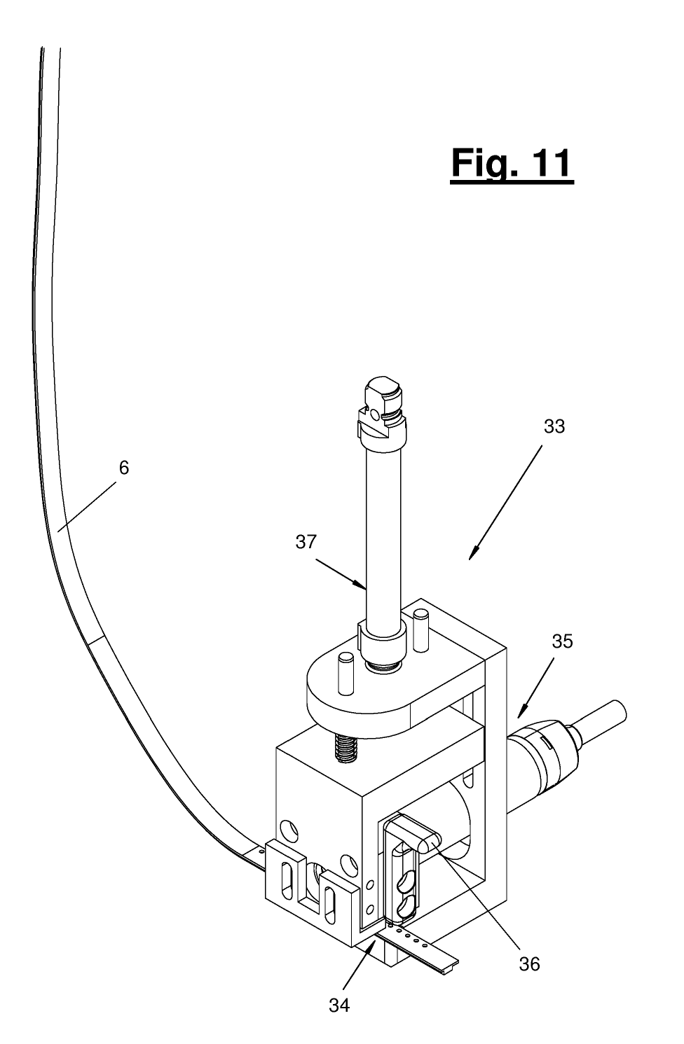

Such a component may be a guide (34) for the tape (6). It may have for example a guide bed on a body of the feed device (33). For guiding purposes, a form-fitting and movable guide means may also be provided for the tape (6), e.g., a spiked roller according to FIG. 10. According to FIG. 11, the tape may have a perforation or another counter-element for the form-fitting guide. The guide (34) may also have a projecting routing means, e.g., a routing strip. It may be used for positioning the feed device in relation to a tape inlet of the processing device (31) and for reliably guiding the tape (6) at the time of transfer.

Another component of the feed device may be a securing device (37), with which the inserted tape (6) is secured to or detached from the guide (34). It may have for example a sled-like clamping means having a cylinder or another drive means. The aforementioned movable guide means, in particular the spiked roller, may also be arranged on the securing device (37), in particular on the clamping means. In this way, the movable guide means, particularly the spiked roller, can also assume a securing function by clamping the tape (6) to the guide bed. The spikes can engage in the perforation of the tape (6) and also secure it.

Another component of the feed device (33) may be a propelling device (35), with which the tape (6) can be driven and moved to the feed device (33). The propelling device (35) may be connected to the movable guide means, particularly the spiked roller. For manual actuation, it may have a rotating knob or similar according to FIG. 9 or a controllable drive according to FIG. 11.

The feed device (33) may also have a component in the form of an actuator (36). External devices can be actuated with it. For example, a tape inlet on a tape carrier of the processing device (31) can be opened and closed. For this purpose, the gripping tool (2) and the for example rigid actuator (36) can be moved correspondingly by the previously described handling device (3), preferably when using its sensing capabilities. The sensing capabilities may also be used for a function check, e.g., for the open and closed positions of the tape inlet and/or for the form-fitting receiving and transporting of the new tape end at the tape inlet.

The second variant of the gripping tool of FIGS. 9 to 11 also exhibits an add-on for the gripping tool (2) with a stabilization device (38) for the gripper (10). It can ensure the secure holding of the received gripped object (4) on the gripper (10). It is particularly advantageous for the flat support arms (11, 12). It balances out their bending elasticity about the transverse axis and holds the support arms (11, 12) in a gripping position on the gripped object (4). The stabilization device (38) may have for example the depicted magnet arrangement, in which the two-sided magnets pull the support arms (11, 12) against each other in the gripping position.

Deviations of the depicted and described embodiment are possible in various ways. In particular, the features of the previously described embodiments and the mentioned deviations may be freely combined, and also interchanged in particular.

The gripped object (4) may be designed in another manner, e.g., as a solid body. Instead of the depicted disk-shape with a rotation-symmetric circumference and plane side surfaces, any other side contour and/or circumferential contour can be present. A disk-like gripped object (4) may for example have an oval or prismatic circumference. It may also have one or more non-planar side surface(s). The recess (7) may be arranged at another location and if applicable off-center. Also variable are the processes executed with a gripped object (4) and the optionally present processing device (31).

The gripper (10) may have a different and optionally single gripping means (15). It may for example have a gripping finger, which is translationally extended and retracted transversely to the arm plane or body plane. A finger-like gripping means (15) may also be formed and actuated by deforming a body. The adjusting device (16) may be modified accordingly in terms of design and function. It may for example have a fluidic drive, which controllably moves a piston-like gripping means (15). The adjusting device (16) can place the gripping means (15) in the gripping position and return it into the release position. Alternately, the return can also take place by another return element, which is designed for example in a compressible or elastic manner. A gear unit (23) of the adjusting device (16) may be omitted or be designed in another way for transmitting a force or motion.

While the present invention has been illustrated by a description of various embodiments, and while these embodiments have been described in considerable detail, it is not intended to restrict or in any way limit the scope of the appended claims to such detail. The various features shown and described herein may be used alone or in any combination. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit and scope of the general inventive concept.

### LIST OF REFERENCE SIGNS

1. Gripping device
2. Gripping tool
3. Handling device, industrial robot
4. Gripped object, tape reel, SMD roll
5. Body, reel body
6. Tape, carrier tape
7. Recess
8. Frame
9. Connection, robot connection
10. Gripper
11. Support arm
12. Support arm
13. Adjustable bearing
14. Open space
15. Gripping means, gripping finger
16. Adjusting device
17. Projection, support and bearing lug
18. Projection, support and bearing lug
19. Control rod
20. Control rod
21. Rod bearing
22. Control drive, cylinder
23. Gear unit
24. Yoke
25. Rack
26. Gear wheel
27. End member
28. Drive element
29. Sensor system
30. Transport means
31. Processing device, placement device
32. Holder, reel holder
33. Feed device
34. Guide
35. Propelling device
36. Actuator
37. Securing device
38. Stabilization device

What is claimed is:

1. Gripping tool for reel-like and/or disk-like gripped objects (4), particularly SMD rolls, characterized in that the gripping tool (2), which can be handled and operated automatically, has a frame (8) with a connection (9), particularly a robot connection and a gripper (10) with a controllable control device (16), which is designed for laterally guiding and for centrally gripping and supporting a gripped object (4).

2-28. (canceled)
